(19) United States
(12) Patent Application Publication
(10) Pub. No.: US 2024/0339377 A1
(43) Pub. Date: Oct. 10, 2024

(54) SEMICONDUCTOR DEVICE

(71) Applicant: Samsung Electronics Co., Ltd., Suwon-si (KR)

(72) Inventors: Junghwan Chun, Suwon-si (KR); Minjae Kang, Suwon-si (KR); Koungmin Ryu, Suwon-si (KR); Jongmin Baek, Suwon-si (KR); Deokyoung Jung, Suwon-si (KR)

(21) Appl. No.: 18/463,550

(22) Filed: Sep. 8, 2023

(30) Foreign Application Priority Data
Apr. 4, 2023 (KR) 10-2023-0043993

(51) Int. Cl. H01L 23/48; H01L 21/768; H01L 23/522

(52) U.S. Cl. CPC H01L 23/481; H01L 21/76898; H01L 23/5226; H01L 23/53295

(57) ABSTRACT

A semiconductor device includes an active region extending on a substrate in a first direction; a device isolation layer on the active region; a source/drain region on the active region; an interlayer insulating layer on the source/drain region; a stopper layer on the interlayer insulating layer; a contact structure passing through the interlayer insulating layer and the stopper layer and electrically connected to the source/drain region; and a conductive through-structure passing through the device isolation layer and the interlayer insulating layer from a lower surface of the substrate, and extending in a third direction, to contact a lower surface of the contact structure and the stopper layer, wherein the stopper layer is in contact with a portion of a side surface of the contact structure, and a lower surface of the stopper layer is lower than an upper surface of the contact structure relative to the substrate.

### CROSS-REFERENCE TO RELATED APPLICATION(S)

This application claims benefit of priority to Korean Patent Application No. 10-2023-0043993 filed on Apr. 4, 2023, in the Korean Intellectual Property Office, the disclosure of which is incorporated herein by reference in its entirety.

### FIELD

The present inventive concept relates to a semiconductor device.

### BACKGROUND

As demand for high performance, high speed, and/or multifunctionality of semiconductor devices increases, a degree of integration of semiconductor devices is increasing. In manufacturing a semiconductor device having a fine pattern corresponding to the high degree of integration of semiconductor devices, it may be required to implement patterns having a fine width or a fine separation distance. In addition, in order to improve a degree of integration, efforts are being made to develop a semiconductor device having a back side power delivery network (BSPDN) structure in which a power rail is disposed on a rear surface of a wafer.

### SUMMARY

An aspect of the present inventive concept is to provide a semiconductor device having an improved degree of integration and improved electrical characteristics.

According to an aspect of the present inventive concept, a semiconductor device includes a substrate; an active region extending on the substrate in a first direction; a device isolation layer on the active region; a gate structure extending in a second direction, intersecting the first direction; a source/drain region on the active region on one side of the gate structure; an interlayer insulating layer on the device isolation layer and on the gate structure and the source/drain region; a stopper layer on the interlayer insulating layer; a contact structure passing through the interlayer insulating layer and the stopper layer and electrically connected to the source/drain region; and a conductive through-structure extending in the first direction, passing through the device isolation layer and the interlayer insulating layer from a lower surface of the substrate, and extending in a third direction, perpendicular to the first and second directions, to contact a lower surface of the contact structure and the stopper layer, wherein the stopper layer is in contact with a portion of a side surface of the contact structure, and a lower surface of the stopper layer is lower than an upper surface of the contact structure relative to the substrate.

According to an aspect of the present inventive concept, a semiconductor device includes a substrate; an active region extending on the substrate in a first direction; a device isolation layer on the active region; a gate structure extending in a second direction, intersecting the first direction; a source/drain region on the active region on one side of the gate structure; an interlayer insulating layer on the device isolation layer and on the gate structure and the source/drain region; a stopper layer on the interlayer insulating layer; a contact structure passing through the interlayer insulating layer and the stopper layer and electrically connected to the source/drain region; and a conductive through-structure extending in the first direction, passing through the device isolation layer and the interlayer insulating layer from a lower surface of the substrate, extending in a third direction, perpendicular to the first and second directions, and electrically connected to the contact structure, wherein the stopper layer is in contact with a portion of a side surface of the contact structure, and a width of the contact structure increases and then decreases in the third direction away from the substrate.

According to an aspect of the present inventive concept, a semiconductor device includes a substrate; an active region extending on the substrate in a first direction; a device isolation layer surrounding the active region on the substrate; a gate structure extending in a second direction, intersecting the first direction; a source/drain region on the active region on one side of the gate structure; an interlayer insulating layer on the device isolation layer and on the gate structure and the source/drain region; a stopper layer on the interlayer insulating layer; a contact structure passing through the interlayer insulating layer and the stopper layer and electrically connected to the source/drain region; and a conductive through-structure extending in the first direction, passing through the device isolation layer and the interlayer insulating layer from a lower surface of the substrate, and extending in a third direction, perpendicular to the first and second directions, to contact a lower surface of the contact structure and the stopper layer, wherein the stopper layer is in contact with a portion of a side surface of the contact structure, the conductive through-structure includes an overlapping portion that vertically overlaps the contact structure in the third direction and a non-overlapping portion that does not vertically overlap the contact structure in the third direction, the overlapping portion is in contact with the lower surface of the contact structure, the non-overlapping portion is in contact with the stopper layer, and an uppermost end of the non-overlapping portion is higher than an uppermost end of the overlapping portion relative to the substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 illustrates a schematic plan view of a semiconductor device according to an embodiment.

FIG. 2 illustrates schematic cross-sectional views of a semiconductor device according to an embodiment.

FIG. 3 illustrates schematic cross-sectional views of a semiconductor device according to an embodiment.

FIG. 4 illustrates schematic cross-sectional views of a semiconductor device according to an embodiment.

FIG. 5 illustrates schematic cross-sectional views of a semiconductor device according to an embodiment.

FIG. 6 illustrates schematic cross-sectional views of a semiconductor device according to an embodiment.

FIG. 7 illustrates schematic cross-sectional views of a semiconductor device according to an embodiment.

FIG. 8 illustrates schematic cross-sectional views of a semiconductor device according to an embodiment.

FIGS. 9A, 9B, 9C, 9D, 9E and 9F illustrate cross-sectional views of a method of manufacturing a semiconductor device according to an embodiment, according to a process sequence.

### DETAILED DESCRIPTION

Hereinafter, preferred embodiments of the present inventive concept will be described with reference to the accompanying drawings. It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items.

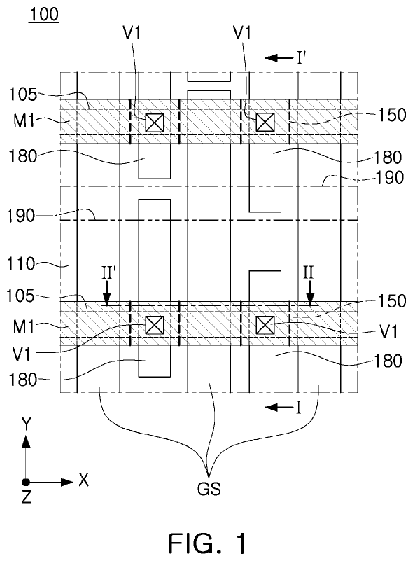

FIG. 1 illustrates a schematic plan view of a semiconductor device according to an embodiment.

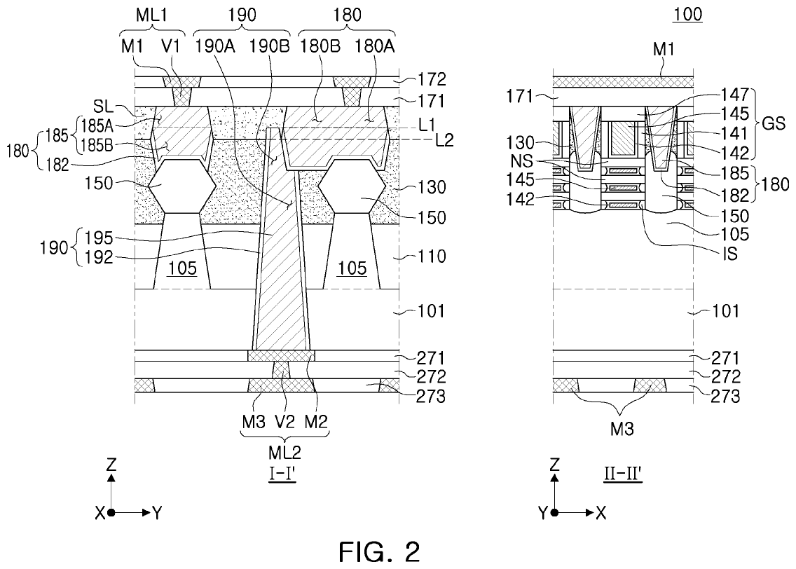

FIG. 2 illustrates schematic cross-sectional views of a semiconductor device according to an embodiment. FIG. 2 illustrates cross-sections of the semiconductor device of FIG. 1, taken along lines I-I′ and II-II′, respectively. For convenience of description, only some components of the semiconductor device are illustrated in FIG. 1.

Referring to FIGS. 1 and 2, a semiconductor device 100 may include a substrate 101, an active region 105 extending in a first direction (X) on the substrate 101, a device isolation layer 110, a plurality of channel layers NS disposed vertically apart from each other on the active region 105, a gate structure GS extending in a second direction (Y), intersecting the first direction (X), a source/drain region 150 disposed on the active region 105 on both (e.g., opposing) sides of the gate structure GS, an interlayer insulating layer 130 covering the gate structure GS and the source/drain region 150, a stopper layer SL covering the interlayer insulating layer 130, a contact structure 180 connected to the source/drain region 150, and a conductive through-structure 190 electrically connected to the source/drain region 150. The semiconductor device 100 may further include a first interconnection portion ML1 and a second interconnection portion ML2.

The substrate 101 may have an upper surface extending in the X and Y-directions. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, or a semiconductor-on-insulator (SeOI) layer.

The substrate 101 may include active regions 105 disposed thereon. However, depending on a description method, the active regions 105 may also be described as a separate configuration, distinguished from the substrate 101.

The active regions 105 may be arranged to extend in the first direction, for example, the X-direction. The active regions 105 may be defined at a predetermined depth from the upper surface in a portion of the substrate 101. The active regions 105 may be formed as a portion of the substrate 101 or may include an epitaxial layer grown from the substrate 101. Each of the active regions 105 may include active fins protruding in an upward direction. The active regions 105, together with the channel structures or layers NS, may form an active structure in which a channel region of a transistor is formed. Each of the active regions 105 may include an impurity region. The impurity region may form at least a portion of a well region of a transistor.

The device isolation layer 110 may be located between adjacent active regions 105 in the Y-direction. Upper surfaces of the active regions 105 may be located on a level, higher than an upper surface of the device isolation layer 110. The active regions 105 may be partially recessed on both (e.g., opposing) sides of the gate structures GS, and the source/drain region 150 may be respectively disposed on the recessed regions.

The device isolation layer 110 may fill a space between the active regions 105, and may define the active regions 105 on the substrate 101. The term “fill” as may be used herein is intended to refer to either completely filling a defined space or partially filling the defined space; that is, the defined space need not be entirely filled but may, for example, be partially filled or have voids or other spaces throughout. The device isolation layer 110 may be formed by, for example, a shallow trench isolation (STI) process. The device isolation layer 110 may expose an upper surface of the active region 105 or partially expose the upper surface of the active region 105. The term “expose,” as may be used throughout the present specification to describe certain intermediate processes in fabricating a completed semiconductor device, is not intended to necessarily require exposure of the particular region, layer, structure or other element in the completed device. The device isolation layer 110 may be formed of an insulating material. The device isolation layer 110 may include, for example, an oxide, a nitride, or combinations thereof.

The plurality of channel layers NS may be disposed vertically spaced apart from each other on the active regions 105. The semiconductor device 100 may further include internal spacers IS disposed parallel to a gate electrode 145. The semiconductor device 100 may be a gate-all-around structure in which the gate electrode 145 may include transistors having a multi bridge channel FET (MBCFET™) structure, which may be a gate-all-around type field effect transistor disposed between the active regions 105 and the channel layers NS and between the plurality of channel layers NS having a nanosheet shape. For example, the semiconductor device 100 may include transistors including the channel layers NS, the source/drain regions 150, and the gate electrode 145.

The plurality of channel layers NS may be disposed in plural, such as two or more thereof, that may be spaced apart from each other in a direction, perpendicular to the upper surfaces of the active regions 105, for example, in a third direction (Z), on the active regions 105. The channel layers NS may be spaced apart from the upper surfaces of the active regions 105 while being connected to the source/drain regions 150. The term “connected” may be used herein to refer to a physical and/or electrical connection. As used herein, when components or layers are referred to as “directly on” or “directly connected” or in “direct contact”, no intervening components or layers are present. The channel layers NS may have a width, equal or similar to a width of each of the active regions 105 in the second direction (Y), and may have a width, equal or similar to a width of the gate structure GS in the first direction (X). In the present embodiment, when the internal spacer IS is employed, each of the channel layers NS may have a width, narrower than a width of a side surface in a lower portion of the gate structure GS.

The plurality of channel layers NS may be formed of a semiconductor material, and may include, for example, at least one of silicon (Si), silicon germanium (SiGe), or germanium (Ge). The channel layers NS may be formed of, for example, the same material as that of the substrate 101. The number and shapes of the channel layers NS constituting one channel structure may be variously changed in embodiments. For example, according to embodiments, a channel layer may be further located in a region in which the active regions 105 are in contact with the gate electrode 145.

The gate structure GS may have a linear shape extending in the second direction (Y). The gate structure GS may be disposed in one or more of the active regions 105. As illustrated in FIG. 2, the gate structure GS may include gate spacers 141, a gate dielectric layer 142 and a gate electrode 145, sequentially disposed between the gate spacers 141, and a gate capping layer 147 disposed on the gate electrode 145. For example, the gate spacers 141 may include an insulating material such as SiOCN, SION, SiCN, or SiN. The gate dielectric layer 142 may be formed as, for example, a silicon oxide film, a high-K film, or combinations thereof. The high-K film may include a material having a dielectric constant, higher than a dielectric constant of the silicon oxide film. For example, the high-K film may include hafnium oxide, hafnium oxynitride, hafnium silicon oxide, lanthanum oxide, lanthanum aluminum oxide, and/or combinations thereof, but is not limited thereto. The gate electrode 145 may include a conductive material, and may include, for example, a metal nitride such as titanium nitride (TiN), tantalum nitride (TaN), or tungsten nitride (WN), and/or a metal material such as aluminum (Al), tungsten (W), molybdenum (Mo), or the like, or a semiconductor material such as doped polysilicon. In some embodiments, the gate electrode 145 may be a multilayer including two or more films. In addition, the gate capping layer 147 may include, for example, silicon nitride, silicon oxynitride, silicon carbonitride, or silicon oxycarbonitride.

The gate structure GS may be disposed to extend over the active regions 105 and the plurality of channel layers NS to cross the active regions 105 and the plurality of channel layers NS. Channel regions of transistors may be formed in the active regions 105 and the plurality of channel layers NS, crossing the gate structure GS. In the present embodiment, the gate dielectric layer 142 may be disposed not only between the active region 105 and the gate electrode 145, but also between the plurality of channel layers NS and the gate electrode 145. The gate electrode 145 may be disposed to fill a space between the plurality of channel layers NS on the active regions 105, and extend into an upper portion of the plurality of channel layers NS. The gate electrode 145 may be spaced apart from the plurality of channel layers NS by the gate dielectric layer 142.

The internal spacers IS may be disposed parallel to the gate electrode 145 between the plurality of channel layers NS. The gate electrode 145 may be spaced apart from the source/drain region 150 by internal spacers IS, and may be electrically separated from each other. The internal spacers IS may have a shape in which side surfaces of the internal spacers IS facing the gate electrode 145 are flat or convexly rounded inward toward the gate electrode 145. The internal spacers IS may be formed of an oxide, a nitride, or an oxynitride, and particularly may be formed of a low-K film. In some other embodiments, the semiconductor device 100 may be implemented to include a vertical field effect transistor (FET) in which an active region extending perpendicularly to an upper surface of the substrate 101 and a gate structure surrounding the active region are disposed. The term “surrounding” or “covering” as may be used herein may not require completely surrounding or covering the described elements or layers, but may, for example, refer to partially surrounding or covering the described elements or layers.

The source/drain region 150 may be disposed on the active region 105 located on both (e.g., opposing) sides of the gate structure GS. The source/drain region 150 may be respectively connected to both (e.g., opposing) end portions of the plurality of channel layers NS in the first direction (e.g., the X-direction). The gate electrode 145 may extend in the second direction (e.g., the Y-direction) to cross the active region 105 while surrounding the plurality of channel layers NS. The gate electrode 145 may be interposed not only in a space between the gate spacers 141 but also in a space between the plurality of channel layers NS.

The internal spacers IS provided between each of the source/drain region 150 and the gate electrode 145 may be included. The internal spacers IS may be provided on both (e.g., opposing) sides of the gate electrode 145 interposed between the plurality of channel layers NS in the first direction (e.g., the X-direction). The plurality of channel layers NS may be respectively connected to the source/drain region 150 on both (e.g., opposing) sides thereof, and the gate electrodes 145 interposed between the plurality of channel layers NS may be electrically insulated from the source/drain region 150 on both (e.g., opposing) sides thereof by the internal spacers IS. The gate dielectric layer 142 may be interposed between the gate electrode 145 and each of the channel layers NS, and may also extend between the gate electrode 145 and the internal spacers IS. As described above, the semiconductor device 100 according to the present embodiment may constitute a gate-all-around type field effect transistor.

The source/drain region 150 may include a selective epitaxial growth (SEG) epitaxial pattern, selectively epitaxially grown, using a recessed surface of the active region 105 (including side surfaces of the plurality of channel layers NS) on both (e.g., opposing) sides of the gate structure GS as seeds (i.e., seed layers). This source/drain region 150 may be also referred to as a raised source/drain (RSD). For example, the source/drain region 150 may be Si, SiGe, or Ge, and may have either an N-type or P-type conductivity. In forming a P-type source/drain region 150, the P-type source/drain region 150 may be re-grown with SiGe, and P-type impurities, e.g., boron (B), indium (In), gallium (Ga), boron trifluoride (BF3), or the like, may be doped. When silicon (Si) is formed in an N-type source/drain region 150, N-type impurities, e.g., phosphorus (P), nitrogen (N), arsenic (As), antimony (Sb), or the like, may be doped. The source/drain region 150 may have different shapes along a crystallographically stable plane during a growth process. For example, as illustrated in FIG. 2A, the source/drain region 150 may have a pentagonal cross-section (in the P-type source/drain region 150), but may have a hexagonal cross-section or a polygonal cross-section having gentle or less sharp angles (in the N-type source/drain region 150).

The interlayer insulating layer 130 may be disposed around the gate structure GS while partially covering the source/drain region 150. For example, the interlayer insulating layer 130 may be formed of a flowable oxide (FOX), tonen silazen (TOSZ), an undoped silica glass (USG), a borosilica glass (BSG), a phosphosilaca glass (PSG), a borophosphosilica glass (BPSG), a plasma enhanced tetraethylorthosilicate (PETEOS), a fluoride silicate glass (FSG), a high density plasma (HDP) oxide, a plasma enhanced oxide (PEOX), a flowable CVD (FCVD) oxide, or combinations thereof.

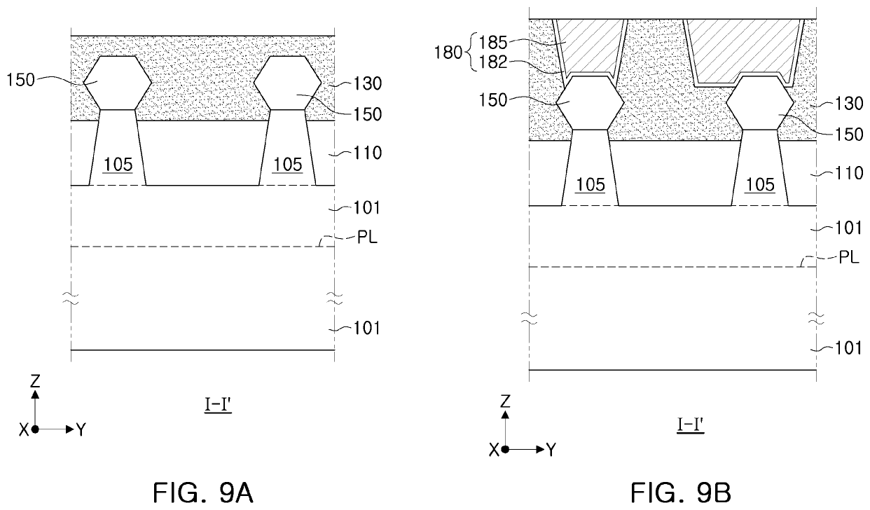

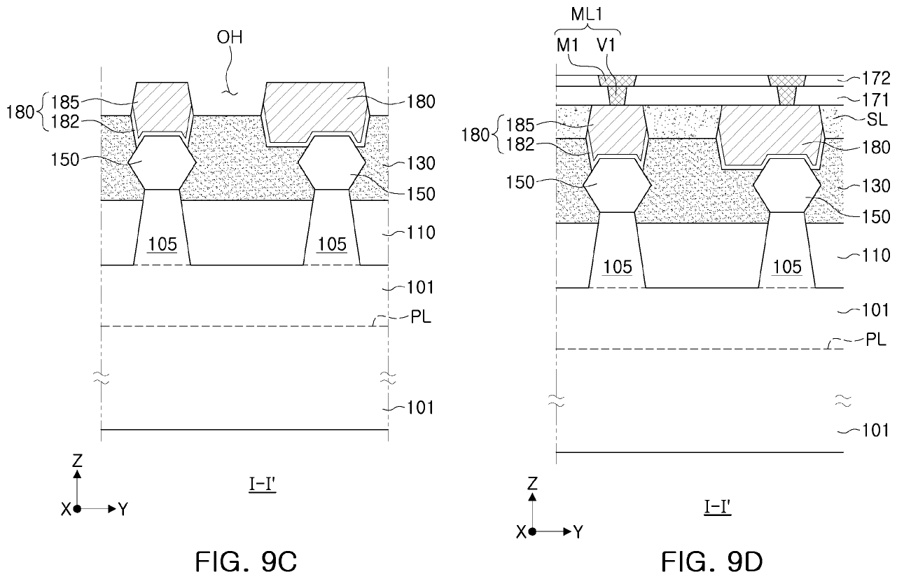

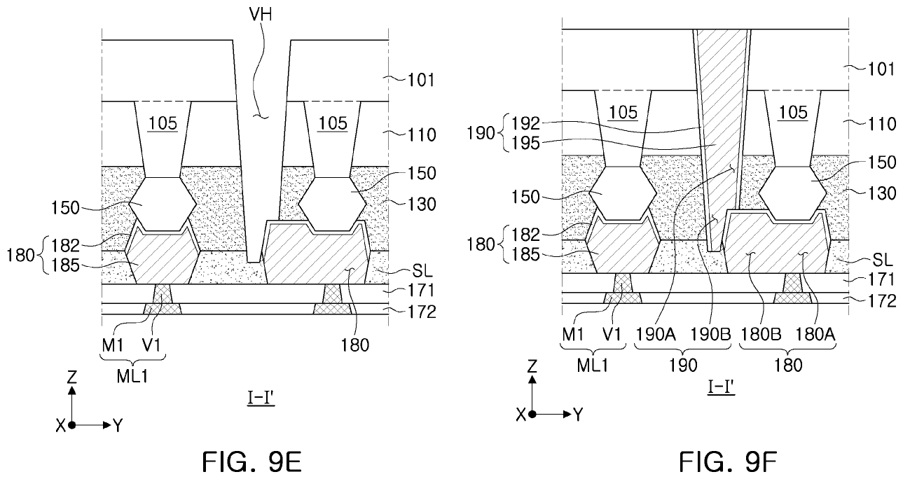

The stopper layer SL may surround a portion of a side surface of the contact structure 180 and a portion of a side surface of the gate structure GS. According to an embodiment, an upper surface of the stopper layer SL may be located on a level substantially equal to an upper surface of the contact structure 180 and an upper surface of the gate structure GS (i.e., the upper surfaces of the stopper layer SL, the contact structure 180, and the gate structure GS may be substantially coplanar), but is not limited thereto. A lower surface of the stopper layer SL may be located on a level, higher than a lower surface of the contact structure 180 and an uppermost end of the source/drain region 150. Since the stopper layer SL may be formed by filling an opening OH after a process of FIG. 9C to be described later, the lower surface of the stopper layer SL may be located on a level, lower than the upper surface of the contact structure 180. The stopper layer SL may be in contact with a portion of a side surface of the contact structure 180. During the process of FIG. 9C, since the interlayer insulating layer 130 and a portion of a side surface of the contact structure 180 may be removed, the stopper layer SL may be in direct contact with a plug conductive layer 185.

A width of the stopper layer SL along the Y-direction may decrease toward the upper surface of the substrate 101 in the Z-direction. The stopper layer SL may include a material having etch selectivity with respect to the contact structure 180. The interlayer insulating layer 130 may include a material having etch selectivity with respect to the stopper layer SL. The stopper layer SL may include a non-conductive material. For example, the stopper layer SL may include an oxide, a nitride, or an oxynitride, and particularly may include a low-k dielectric. For example, the stopper layer SL may include at least one of SiO₂, SiN, SiC, SiCN, SiOC, SION, AlO, SnO, or SiOCN. Since a material composition of the stopper layer SL is different from a material composition of the interlayer insulating layer 130, they may be substantially distinguished by analysis such as transmission electron microscopy energy-dispersive X-ray spectroscopy (TEM-EDX) or the like.

The stopper layer SL may be disposed on the interlayer insulating layer 130, and may serve as an etch stop layer in an etching process for forming the conductive through-structure (e.g., a conductive through via) 190 due to a difference in etching selectivity with respect to the interlayer insulating layer 130. Therefore, an etch margin, an align margin, and/or an overlay margin of the conductive through-structure 190 may be secured, and occurrence of leakage current between the conductive through-structure 190 and an upper interconnection layer may be reduced or prevented.

The contact structure 180 may pass through the interlayer insulating layer 130, and may be connected to the source/drain region 150. The contact structure 180 may interconnect the source/drain region 150 and the first interconnection portion ML1. A separate gate contact structure may be further disposed on the gate electrode 145 in a region not illustrated. The contact structure 180 may be configured to connect the source/drain region 150 and the conductive through-structure 190. Specifically, the contact structure 180 employed in the present embodiment may include a first contact portion 180A connected to the source/drain region 150, and a second contact portion 180B connected to the conductive through-structure 190. The second contact portion 180B may extend from the first contact portion 180A in the second direction (e.g., the Y-direction), and may be more easily connected or more accurately aligned to the conductive through-structure 190.

The contact structures 180 may include a metal silicide layer located on a lower end thereof, and may further include a barrier layer 182 and a plug conductive layer 185, disposed on the metal silicide layer and sidewalls. According to an embodiment, the barrier layer 182 may be disposed along a portion of a sidewall and a lower surface of the contact structure 180. For example, the barrier layer 182 may not be disposed on an upper portion of the sidewall of the contact structure 180. Specifically, in a process of forming the stopper layer SL, since a portion of the sidewall of the contact structure 180 may be removed, the plug conductive layer 185 may include a first portion 185A contacting the stopper layer SL, and a second portion 185B spaced apart from the stopper layer SL by the barrier layer 182. According to an embodiment, since the stopper layer SL serves as an etch stop layer in a process of forming the conductive through-structure 190, the conductive through-structure 190 may be spaced apart from the first portion 185A.

The barrier layer 182 may include, for example, a metal nitride such as titanium nitride (TiN), tantalum nitride (TaN), or tungsten nitride (WN). The plug conductive layer 185 may include, for example, a metal material such as aluminum (Al), tungsten (W), molybdenum (Mo), or the like. In embodiments, the number and arrangement of conductive layers constituting the contact structure 180 may be variously changed.

The contact structure 180 may pass through the interlayer insulating layer 130 and the stopper layer SL, and may be connected to the source/drain region 150 and the conductive through-structure 190. For example, the first contact portion 180A may be connected to the source/drain region 150, and the second contact portion 180B may be connected to the conductive through-structure 190.

A width of the contact structure 180 may increase and then decrease in the third direction (Z), farther away or with distance from the upper surface of the substrate 101. According to an embodiment, in a region in which the contact structure 180 and the stopper layer SL horizontally overlap, the width of the contact structure 180 may increase toward the upper surface of the substrate 101 in the third direction (Z). The width of the contact structure 180 may be maximum on a level, substantially equal to a level L2 of the lower surface of the stopper layer SL.

The conductive through-structure 190 may be buried in the interlayer insulating layer 130 and the device isolation layer 110 to be electrically connected to the source/drain region 150. The conductive through-structure 190 may be disposed to electrically connect the contact structure 180 and the second interconnection portion ML2. At least a portion of the conductive through-structure 190 may overlap the contact structure 180 in the Y-direction and the Z-direction, perpendicular to the upper surface of the substrate 101. Components or layers described with reference to “overlap” in a particular direction may be at least partially obstructed by one another when viewed along a line extending in the particular direction or in a plane perpendicular to the particular direction.

The conductive through-structure 190 may have a side surface that is inclined to increase in width toward the substrate 101 due to an aspect ratio, but is not limited thereto. In the conductive through-structure 190, both (e.g., opposing) side surfaces in the Y-direction may include regions having different inclinations. The conductive through-structure 190 may include a first contact plug 195 and a first insulating liner 192 surrounding a side surface of the first contact plug 195.

The first contact plug 195 may include, for example, Cu, Co, Mo, Ru, W, or alloys thereof. In the present embodiment, first contact plugs 195 may include different conductive materials. In some embodiments, the first contact plug 195 may include Mo.

The first insulating liner 192 may include, for example, an oxide, a nitride, an oxynitride, SiO₂, SiN, SiCN, SiC, SiCOH, SiON, Al₂O₃, AlN, or combinations thereof. The first insulating liner 192 may be disposed to cover portions of side surfaces of the first contact plug 195.

Although not illustrated, the conductive through-structure 190 may include a conductive barrier. The conductive barrier may include, for example, Ta, TaN, Mn, MnN, WN, Ti, TiN, or combinations thereof, and may cover the side surface of the first contact plug 195. For example, the conductive barrier may be disposed between the first insulating liner 192 and the first contact plug 195.

The conductive through-structure 190 may pass through at least a portion of the device isolation layer 110. A lower surface of the conductive through-structure 190 may be in contact with the second interconnection portion ML2. According to an embodiment, the conductive through-structure 190 may pass through the interlayer insulating layer 130 and at least a portion of the device isolation layer 110, and may extend in the third direction (Z).

An upper surface or an upper end of the conductive through-structure 190 may be located on a level, higher than upper surfaces or upper ends of the source/drain regions 150. The conductive through-structure 190 may be in contact with the contact structure 180 through the upper surface thereof.

The conductive through-structure 190 may include an overlapping portion 190A vertically overlapping the contact structure 180, and a non-overlapping portion 190B not vertically overlapping the contact structure 180. According to an embodiment, the overlapping portion 190A may be in contact with the lower surface of the contact structure 180. For example, in the second contact portion 180B of the contact structure 180, the conductive through-structure 190 may be in contact with the contact structure 180.

The non-overlapping portion 190B may be in contact with the lower surface of the stopper layer SL, and an uppermost end of the non-overlapping portion 190B may be located on a level, higher than an uppermost end of the overlapping portion 190A.

The conductive through-structure 190 may extend in the first direction (X), may be in contact with the lower surface of the contact structure 180 and the lower surface of the stopper layer SL, may pass through the device isolation layer 110 and the interlayer insulating layer 130 from the lower surface of the substrate 101, and may extend into the stopper layer SL in the Z-direction. According to an embodiment, the conductive through-structure 190 may pass through a portion of the stopper layer SL, and a level L1 of the uppermost end of the non-overlapping portion 190B may be higher than the level L2 of the lower surface of the stopper layer SL relative to the substrate, but is not limited thereto.

The stopper layer SL may serve as an etch stop layer in an etching process for forming the conductive through-structure 190. Therefore, although there is a region in which the conductive through-structure 190 and the contact structure 180 do not vertically overlap, occurrence of leakage current between the conductive through-structure 190 and an upper interconnection layer may be reduced or prevented. For this reason, the level L1 of the uppermost end of the non-overlapping portion 190B may be lower than the upper surface of the contact structure 180 and the upper surface of the stopper layer SL. According to an embodiment, the conductive through-structure 190 may be spaced apart from the first interconnection portion ML1 by the stopper layer SL. The conductive through-structure 190 may be in contact with the lower surface of the stopper layer SL and the side surface of the contact structure 180. Since the contact structure 180 is formed and the substrate 101 is turned over to form the conductive through-structure 190, a width of the conductive through-structure 190 may decrease toward the stopper layer SL.

The first interconnection portion ML1 may include a plurality of first dielectric layers 171 and 172, a metal interconnection M1, and a metal via V1. The plurality of first dielectric layers 171 and 172 may include first dielectric layers 171 and 172 disposed on the interlayer insulating layer 130. The metal interconnection M1 may be formed in a first upper dielectric layer 172, and the metal via V1 may be formed in a first lower dielectric layer 171. In this case, the metal via V1 may be connected to the contact structure 180 through the metal interconnection M1. According to an embodiment, the first interconnection portion ML1 may be disposed on the stopper layer SL, and may be electrically connected to the contact structure 180.

The first dielectric layers 171 and 172 may include, for example, at least one of an oxide, a nitride, or an oxynitride, and may include silicon oxide, silicon oxynitride, SiOC, SiCOH, or combinations thereof. For example, the metal interconnection M1 and the metal via V1 may include copper or a copper-containing alloy. In some embodiments, the metal interconnection M1 and the metal via V1 may be formed together using a dual-damascene process.

According to an embodiment, the second interconnection portion ML2 connected to the conductive through-structure 190 may be disposed on the lower surface of the substrate 101. The second interconnection portion ML2 employed in the present embodiment can be understood as an interconnection portion replacing a portion of the first interconnection portion ML1, which may be BEOL. In the present embodiment, the second interconnection portion ML2 may be an interconnection portion for power delivery, and the first interconnection portion ML1 may be provided as an interconnection portion for signal transmission. In a similar manner to the first interconnection portion ML1, the second interconnection portion ML2 may include a plurality of second dielectric layers 271, 272, and 273, metal interconnections M2 and M3, and a metal via V2.

As such, in the present embodiment, a signal network may be configured to pass through the contact structure 180 from the first interconnection portion ML1 located on the upper surface of the substrate 101, to be connected to a device region (e.g., the source/drain region 150 and the gate electrode 145), and a power delivery network may be configured to pass through the substrate 101 from the second interconnection portion ML2 located on the lower surface of the substrate 101, to be connected to a device region (e.g., the source/drain region 150).

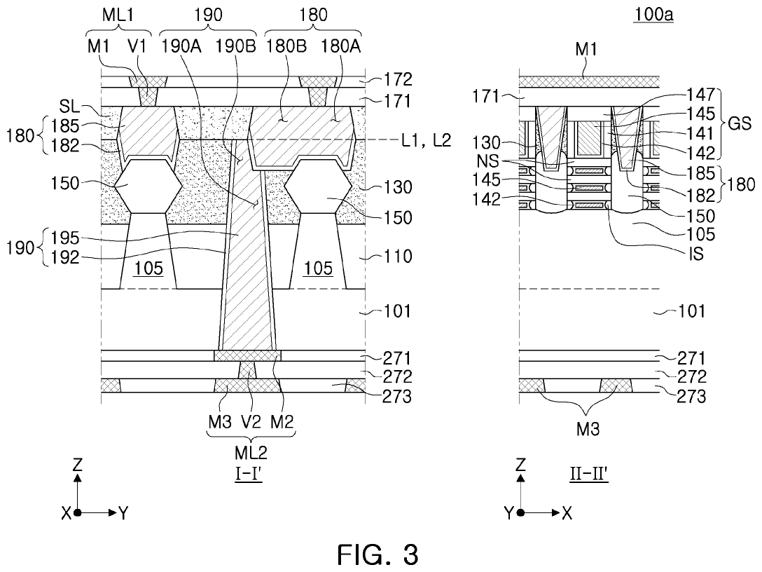

FIG. 3 is schematic cross-sectional views of a semiconductor device 100a according to an embodiment.

Referring to FIG. 3, in a semiconductor device 100a, a level L2 of a lower surface of a stopper layer SL may be substantially equal to a level L1 of an upper surface of a conductive through-structure 190. According to an embodiment, the level L2 of the lower surface of the stopper layer SL may be substantially equal to the level L1 of an uppermost end of a non-overlapping portion 190B of the conductive through-structure 190. The conductive through-structure 190 may be in contact with a second contact portion 180B. For example, the conductive through-structure 190 may be in contact with the lower surface of the stopper layer SL and a side surface of a contact structure 180.

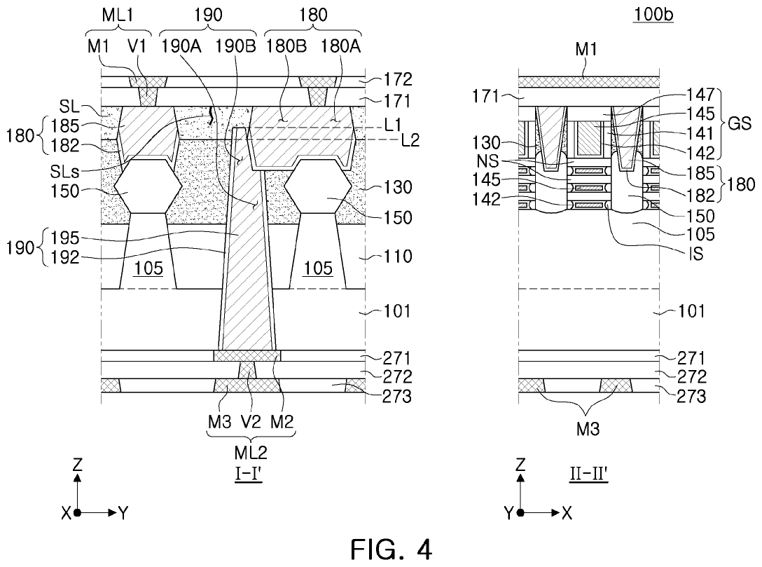

FIG. 4 is schematic cross-sectional views of a semiconductor device 100b according to an embodiment.

Referring to FIG. 4, a semiconductor device 100b may further include a discontinuity or seam SLs extending in the Z-direction in a stopper layer SL. The stopper layer SL may be formed by, for example, an atomic layer deposition (ALD) process. The seam SLs may be formed along a central axis of the stopper layer SL, but is not limited thereto. The seam SLs may also be applied to other embodiments.

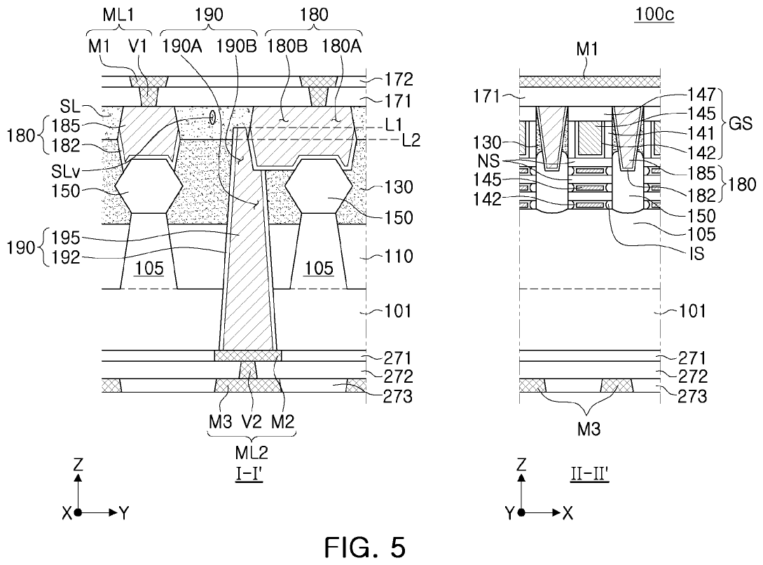

FIG. 5 is schematic cross-sectional views of a semiconductor device 100c according to an embodiment.

Referring to FIG. 5, a semiconductor device 100c may further include a void SLv. The void SLv may be formed by, for example, an atomic layer deposition (ALD) process. As a process of FIG. 9D (to be described later) is performed, a portion in which an opening OH is not filled may be defined as the void SLv. The void SLv may include air, or a gas formed of a material used in a process of manufacturing the semiconductor device 100c. The void SLv may also be applied to other embodiments.

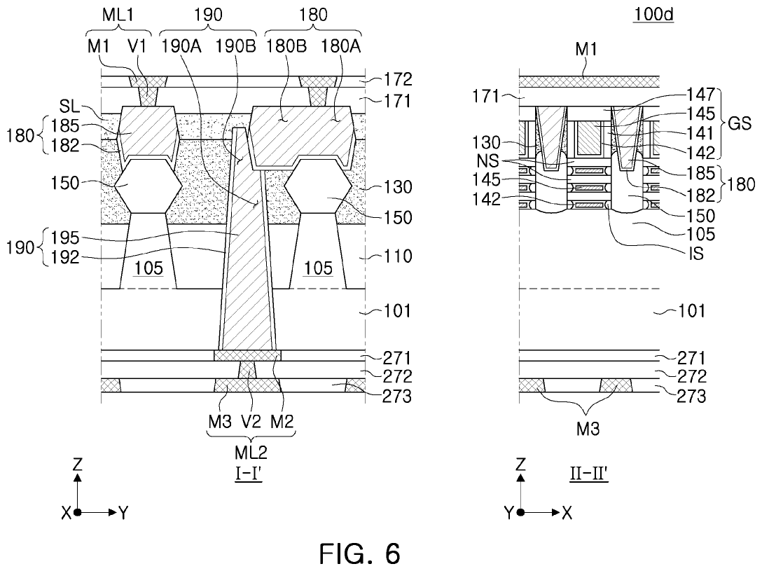

FIG. 6 is schematic cross-sectional views of a semiconductor device 100d according to an embodiment.

Referring to FIG. 6, an upper surface of a stopper layer SL of a semiconductor device 100d may be located on a level, lower than an upper surface of a contact structure 180. This may be due to etch selectivity between the stopper layer SL and the contact structure 180 during a CMP process of FIG. 9D. Since the stopper layer SL may be removed more than the contact structure 180, the upper surface of the stopper layer SL may be located on a level, lower than the upper surface of the contact structure 180. The upper surface of the stopper layer SL is illustrated as being flat, but is not limited thereto, and may have a downwardly convex shape.

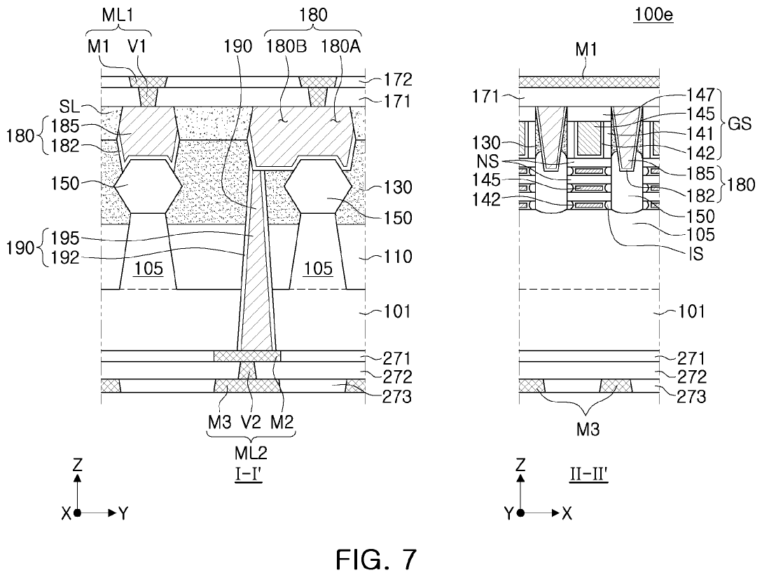

FIG. 7 is schematic cross-sectional views of a semiconductor device 100e according to an embodiment.

Referring to FIG. 7, in a semiconductor device 100e, a conductive through-structure 190 may not be in contact with a stopper layer SL. According to an embodiment, an uppermost end of an overlapping portion 190A of the conductive through-structure 190 may be located on a level, lower than a lower surface of the stopper layer SL. The conductive through-structure 190 may be in contact with a second contact portion 180B of a contact structure 180, and may be in contact with a side surface of the contact structure 180.

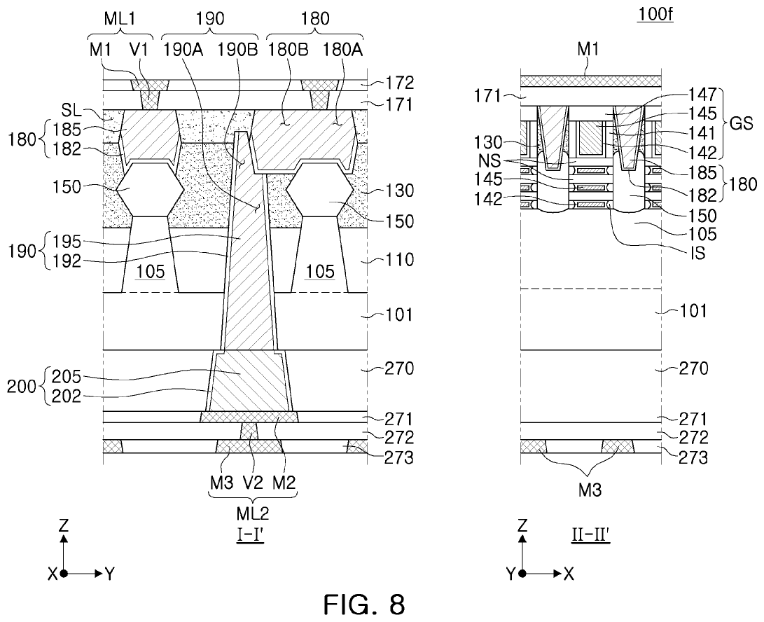

FIG. 8 is schematic cross-sectional views of a semiconductor device 100f according to an embodiment.

Referring to FIG. 8, a semiconductor device 100f may further include a lower interlayer insulating layer 270 and a power delivery structure 200 in the semiconductor device 100 of FIG. 2. The lower interlayer insulating layer 270 may include at least one of an oxide, a nitride, or an oxynitride, or may include combinations thereof.

The power delivery structure 200 may extend from a lower surface of the lower interlayer insulating layer 270 toward an upper surface of the lower interlayer insulating layer 270, and may be electrically connected to a conductive through-structure 190. The power delivery structure 200 may be connected to the conductive through-structure 190 in a portion or interface in which a substrate 101 and the lower interlayer insulating layer 270 are in contact with each other, but is not limited thereto. According to another embodiment, the power delivery structure 200 may be in contact with a bottom surface of the conductive through-structure 190 in the substrate 101. According to an embodiment, the power delivery structure 200 may have a rail shape extending in the first direction (X). The power delivery structure 200 may be disposed below the conductive through-structure 190, and may be connected to a lower end or a lower surface of the conductive through-structure 190. According to an embodiment, the power delivery structure 200 may be in contact with a lower surface of a first contact plug 195, and may extend in the first direction (X). The power delivery structure 200 may form a backside power delivery network (BSPDN) that applies power or ground voltage, and may also be referred to as a buried power rail. For example, the power delivery structure 200 may be a buried interconnection line extending below the conductive through-structure 190 in one direction, for example, in the X-direction, but a shape of the power delivery structure 200 is not limited thereto. The power delivery structure 200 may be further connected to a conductive through-structure 190, which is not illustrated, in a region not illustrated.

The power delivery structure 200 may have side surfaces inclined to decrease a width in an upward direction. For example, the power delivery structure 200 may have a trapezoidal shape in cross-section. The power delivery structure 200 may include a second contact plug 205 and a second insulating liner 202 surrounding a side surface of the second contact plug 205.

The second contact plug 205 may include, for example, Cu, Co, Mo, Ru, W, or alloys thereof. In the present embodiment, the second contact plug 205 may include a conductive material, different from a conductive material of the first contact plug 195. The second contact plug 205 may include Cu or W.

The second insulating liner 202 may cover at least a portion of upper and side surfaces of the second contact plug 205. Side surfaces of the second insulating liner 202 may be covered with the lower interlayer insulating layer 270. The second insulative liner 202 may include, for example, an oxide, a nitride, an oxynitride, SiO₂, SiN, SiCN, SiC, SiCOH, SiON, Al₂O₃, AlN, or combinations thereof. The second insulating liner 202 may be disposed to cover portions of side surfaces of the second contact plug 205.

Although not illustrated, the power delivery structure 200 may include a conductive barrier. The conductive barrier may include, for example, Ta, TaN, Mn, MnN, WN, Ti, TiN, or combinations thereof, and may cover a side surface of the second contact plug 205. For example, the conductive barrier may be disposed between the second insulating liner 202 and the second contact plug 205.

The conductive through-structure 190 may be disposed to electrically connect a contact structure 180 and the power delivery structure 200. The second interconnection portion ML2 may be connected to the power delivery structure 200 on a lower surface of the conductive through-structure 190. The power delivery structure 200 may be further included as a component in the semiconductor device 100 of FIG. 2, but is not limited thereto, and may be further included as a component in other embodiments.

FIGS. 9A, 9B, 9C, 9D, 9E and 9F are cross-sectional views illustrating a method of manufacturing a semiconductor device 100 according to an embodiment, according to a process sequence. FIGS. 9A, 9B, 9C, 9D, 9E and 9F illustrate cross-sections of the semiconductor device 100 of FIG. 1, taken along line I-I′.

Referring to FIG. 9A, a gate-all-around type field effect transistor may be formed on an upper surface of a substrate 101. Specifically, such a transistor may include an active region 105, a plurality of channel layers NS stacked and spaced apart from each other on the active region 105, a gate structure GS crossing the active region 105, and a source/drain region 150 disposed on the active region 105 on both (e.g., opposing) sides of the gate structure GS and connected to both side surfaces of the plurality of channel layers NS. An interlayer insulating layer 130 covering the source/drain region 150 and the gate structure GS may be further formed.

Referring to FIG. 9B, a contact structure 180 may be formed. A contact hole passing through at least a portion of the interlayer insulating layer 130 and exposing the source/drain region 150 may be formed. A width of the contact hole in the Y-direction may be greater than a width of the source/drain region 150 in the Y-direction. After depositing a barrier layer 182 to fill the contact hole, a metal-semiconductor compound layer may be formed on a bottom surface of the contact hole by performing a process such as a silicide process. A plug conductive layer 185 may be formed by depositing a conductive material to fill the contact hole. By performing a planarization process such as CMP, an upper surface of the contact structure 180 may be substantially coplanar with an upper surface of the interlayer insulating layer 130.

Referring to FIG. 9C, an opening OH may be formed by recessing a portion of the interlayer insulating layer 130 and a portion of the contact structure 180. The interlayer insulating layer 130 may be formed of a material having etch selectivity with respect to the contact structure 180. The interlayer insulating layer 130 may be selectively etched with respect to the contact structure 180 by, for example, an etching process, and may be partially removed from the upper surface of the contact structure 180 in the Z-direction. In this case, a portion of a side surface of the contact structure 180 may be removed. For example, a portion of the barrier layer 182 and a portion of the plug conductive layer 185 may be removed. A width of the opening OH in the Y-direction may decrease toward the upper surface of the substrate 101. In addition, in a region in which the contact structure 180 horizontally overlaps the opening OH, the contact structure 180 may have a shape in which a width in the Y-direction decreases in the Z-direction, away from the upper surface of the substrate 101. For example, the contact structure 180 may have a tapered shape, but is not limited thereto.

Referring to FIG. 9D, a stopper layer SL may be formed to fill the opening OH. The stopper layer SL may be formed to cover the contact structure 180 and the gate structure GS (refer to FIG. 2). The stopper layer SL may be formed by a deposition process. For example, the seam SLs of FIG. 4 and the void SLv of FIG. 5 may be formed during an atomic layer deposition (ALD) process. After depositing the stopper layer SL, a CMP process may be performed to expose the upper surface of the contact structure 180. An upper surface of the stopper layer SL may be substantially coplanar with the upper surface of the contact structure 180, but is not limited thereto. For example, as shown in the semiconductor device 100d of FIG. 6, the upper surface of the stopper layer SL may be located on a level, lower than the upper surface of the contact structure 180.

Referring to FIG. 9E, after forming a first interconnection portion ML1 on the contact structure 180 and the stopper layer SL, the substrate 101 may be turned over, and a back grinding process may be performed on the upper surface (i.e., the back surface) of the substrate 101. A vertical hole VH may be formed extending into the back surface of the substrate 101.

In FIG. 9E, for understanding, a mirror image of the structure illustrated in FIG. 9D is illustrated. To reduce a thickness of the substrate 101, a back grinding process may be performed on the upper surface of the substrate 101. For example, the back grinding process may be performed up to a portion indicated by “PL” in FIG. 9D. The vertical hole VH may be formed to pass through the substrate 101 and the interlayer insulating layer 130. The vertical hole VH may include a portion of which width in the Y-direction decreases in the Z-direction, away from a lower surface of the substrate 101. The vertical hole VH may pass through at least a portion of the stopper layer SL. The interlayer insulating layer 130 may have etch selectivity with respect to the stopper layer SL and the contact structure 180. In the process of forming the vertical hole VH, a portion of the contact structure 180 may be exposed. Since the interlayer insulating layer 130 has etch selectivity with respect to the stopper layer SL, only a portion of the stopper layer SL may be removed. The stopper layer SL may serve as an etch stop layer. Therefore, an etch margin, an align margin, and/or an overlay margin of a conductive through-structure 190 may be secured, and occurrence of leakage current between the conductive through-structure 190 and an upper interconnection layer may be reduced or prevented.

Referring to FIG. 9F, a first insulating liner 192 may be formed on an inner surface of the vertical hole VH, and a first contact plug 195 may be formed to fill the vertical hole VH.

The first insulating liner 192 may be conformally deposited not only on an inner surface of the vertical hole VH, but also on the upper surface of the substrate 101, and then the first insulating liner 192 formed below the vertical hole VH may be removed by anisotropic etching. For example, the deposition process may be formed by an atomic layer deposition (ALD) process, a chemical vapor deposition (CVD) process, or a physical vapor deposition (PVD) process. Subsequently, after a conductive material is deposited to fill the first contact plug 195 in the vertical hole VH, a planarization process such as CMP may be performed to remove a material located on the substrate 101 together. As a result, the conductive through-structure 190 extending from the upper surface of the substrate 101 toward the stopper layer SL and the contact structure 180 may be formed.

Referring now to FIG. 2 together, the semiconductor device 100 illustrated in FIG. 2 may be manufactured by forming a second interconnection portion ML2 connected to the conductive through-structure 190 in a subsequent process.

To manufacture the semiconductor device 100f illustrated in FIG. 8, a lower interlayer insulating layer 270 may be formed on the upper surface of the substrate 101 and a power delivery structure 200 may be formed to pass or extend through the lower interlayer insulating layer 270 to be connected to the conductive through-structure 190. For example, after forming a hole passing through at least a portion of the lower interlayer insulating layer 270, a second insulating liner 202 may be formed on the inner surface of the hole, and a second contact plug 205 may be formed by depositing a conductive material to fill the hole. The semiconductor device 100f illustrated in FIG. 8 may be manufactured by forming the second interconnection portion ML2 connected to the power delivery structure 200 on the lower interlayer insulating layer 270. The power delivery structure 200 may be further included as a component in other embodiments.

A semiconductor device having an improved degree of integration and improved electrical characteristics, according to embodiments of the present inventive concept, may be provided by including a stopper layer on or covering an interlayer insulating layer and covering a portion of a side surface of a contact structure, to secure or increase an etch margin, an alignment margin, and an overlay margin in a process of forming a conductive through-structure, and to reduce or prevent leakage current.

Various advantages and effects of the present inventive concept are not limited to the above, and will be understood with reference to examples provided herein describing specific embodiments of the present inventive concept.

While embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate;
an active region extending on the substrate in a first direction;
a device isolation layer on the active region;
a gate structure extending in a second direction, intersecting the first direction;
a source/drain region on the active region on one side of the gate structure;
an interlayer insulating layer on the device isolation layer and on the gate structure and the source/drain region;
a stopper layer on the interlayer insulating layer, wherein the stopper layer comprises a different material than the interlayer insulating layer;
a contact structure passing through the interlayer insulating layer and the stopper layer and electrically connected to the source/drain region; and
a conductive through-structure extending in the first direction, passing through the device isolation layer and the interlayer insulating layer from a lower surface of the substrate, and extending in a third direction, perpendicular to the first and second directions, to contact a lower surface of the contact structure and the stopper layer,
wherein the stopper layer is in contact with a portion of a side surface of the contact structure, and
a lower surface of the stopper layer is lower than an upper surface of the contact structure, relative to the substrate.

2. The semiconductor device of claim 1, wherein a portion of the contact structure that passes through the stopper layer has a width that increases toward the substrate in the third direction.

3. The semiconductor device of claim 1, wherein the lower surface of the stopper layer is higher than the lower surface of the contact structure and an uppermost end of the source/drain region relative to the substrate.

4. The semiconductor device of claim 1, wherein a width of the conductive through-structure decreases toward the stopper layer.

5. The semiconductor device of claim 1, wherein the stopper layer comprises a seam therein extending in the third direction.

6. The semiconductor device of claim 1, wherein an upper surface of the stopper layer is substantially coplanar with the upper surface of the contact structure and an upper surface of the gate structure.

7. The semiconductor device of claim 1, wherein an upper surface of the stopper layer is lower than an upper surface of the contact structure relative to the substrate.

8. The semiconductor device of claim 1, further comprising:
a plurality of channel layers on the active region and spaced apart from each other in the third direction,
wherein the gate structure includes a gate electrode extending in the second direction and on each of the plurality of channel layers, and a gate dielectric layer between each of the plurality of channel layers and the gate electrode.

9. The semiconductor device of claim 1, further comprising:
a lower interlayer insulating layer on the lower surface of the substrate; and
a power delivery structure extending from a lower surface of the lower interlayer insulating layer toward an upper surface of the lower interlayer insulating layer, and electrically connected to the conductive through-structure.

10. The semiconductor device of claim 9, further comprising:
a first interconnection portion on the stopper layer and electrically connected to the contact structure; and
a second interconnection portion electrically connected to the power delivery structure on a lower surface of the conductive through-structure,
wherein the conductive through-structure is spaced apart from the first interconnection portion by the stopper layer.

11. A semiconductor device comprising:
a substrate;
an active region extending on the substrate in a first direction;
a device isolation layer on the active region;
a gate structure extending in a second direction, intersecting the first direction;
a source/drain region on the active region on one side of the gate structure;
an interlayer insulating layer on the device isolation layer and on the gate structure and the source/drain region;
a stopper layer on the interlayer insulating layer, wherein the stopper layer comprises a different material than the interlayer insulating layer;
a contact structure passing through the interlayer insulating layer and the stopper layer and electrically connected to the source/drain region; and
a conductive through-structure extending in the first direction, passing through the device isolation layer and the interlayer insulating layer from a lower surface of the substrate, extending in a third direction, perpendicular to the first and second directions, and electrically connected to the contact structure,
wherein the stopper layer is in contact with a portion of a side surface of the contact structure, and
a width of the contact structure increases and then decreases in the third direction away from the substrate.

12. The semiconductor device of claim 11, wherein the conductive through-structure is in contact with a lower surface of the stopper layer and the side surface of the contact structure, and passes through at least a portion of the stopper layer.

13. The semiconductor device of claim 11, wherein the contact structure comprises:
a barrier layer along a portion of a sidewall and a lower surface of the contact structure and a plug conductive layer on the barrier layer,
wherein the plug conductive layer includes a first portion directly contacting the stopper layer, and a second portion spaced apart from the stopper layer by the barrier layer.

14. The semiconductor device of claim 13, wherein the conductive through-structure is spaced apart from the first portion.

15. The semiconductor device of claim 11, wherein the contact structure has a maximum width at a lower surface of the stopper layer.

16. The semiconductor device of claim 15, wherein the lower surface of the stopper layer is substantially coplanar with an upper surface of the conductive through-structure.

17. A semiconductor device comprising:
a substrate;
an active region extending on the substrate in a first direction;
a device isolation layer surrounding the active region on the substrate;
a gate structure extending in a second direction, intersecting the first direction;
a source/drain region on the active region on one side of the gate structure;
an interlayer insulating layer on the device isolation layer and on the gate structure and the source/drain region;
a stopper layer on the interlayer insulating layer, wherein the stopper layer comprises a different material than the interlayer insulating layer;
a contact structure passing through the interlayer insulating layer and the stopper layer and electrically connected to the source/drain region; and
a conductive through-structure extending in the first direction, passing through the device isolation layer and the interlayer insulating layer from a lower surface of the substrate, and extending in a third direction, perpendicular to the first and second directions, to contact a lower surface of the contact structure and the stopper layer,
wherein the stopper layer is in contact with a portion of a side surface of the contact structure,
the conductive through-structure includes an overlapping portion that overlaps the contact structure in the third direction and a non-overlapping portion that does not overlap the contact structure in the third direction,
the overlapping portion is in contact with the lower surface of the contact structure,
the non-overlapping portion is in contact with the stopper layer, and
an uppermost end of the non-overlapping portion is higher than an uppermost end of the overlapping portion relative to the substrate.

18. The semiconductor device of claim 17, wherein the conductive through-structure passes through a portion of the stopper layer,
the uppermost end of the non-overlapping portion is higher than a lower surface of the stopper layer.

19. The semiconductor device of claim 17, wherein the uppermost end of the non-overlapping portion is lower than an upper surface of the contact structure and an upper surface of the stopper layer.

20. The semiconductor device of claim 17, wherein a lower surface of the stopper layer is substantially coplanar with an upper surface of the non-overlapping portion.
